(19) United States
(12) Patent Application Publication
(10) Pub. No.: US 2012/0324723 A1
(43) Pub. Date: Dec. 27, 2012

(54) METHOD OF MANUFACTURING CORELESS SUBSTRATE

(75) Inventors: Myeong Ho Hong, Gyunggi-do (KR); Byung Moon Kim, Gyunggi-do (KR); Hyun Hee Ku, Gyunggi-do (KR); Soon Oh Jung, Gyunggi-do (KR); Jae Joon Lee, Gyunggi-do (KR)

(73) Assignee: SAMSUNG ELECTRO-MECHANICS CO., LTD., Gyunggi-do (KR)

(21) Appl. No.: 13/448,869

(22) Filed: Apr. 17, 2012

(30) Foreign Application Priority Data
Jun. 24, 2011 (KR) 1020110061871

(51) Int. Cl. H05K 3/00

(52) U.S. Cl. 29/829

(57) ABSTRACT

The present invention has been made in an effort to provide a method of manufacturing a coreless substrate that forms an opening by patterning a dry film for forming the opening onto one surface of a carrier, separating the carrier from the substrate, and removing only the dry film for forming the opening. In the present invention, since the pad can be exposed by removing only the dry film for forming the opening, a process time for forming the opening can be reduced and since a process is simple, a cost is saved.

### CROSS REFERENCE TO RELATED APPLICATION

This application claims the benefit of Korean Patent Application No. 10-2011-0061871, filed on Jun. 24, 2011, entitled “Method of Manufacturing Coreless Substrate” which is hereby incorporated by reference in its entirety into this application.

### BACKGROUND OF THE INVENTION

1. Technical Field

The present invention relates to a method of manufacturing a coreless substrate.

2. Description of the Related Art

In general, in a printed circuit board, wirings are formed on one surface or both surfaces of a board made of various thermosetting synthetic resins by copper foils and an integrated circuit (IC) or electronic components are placed and fixed on the board and electrical wirings among them are implemented coated with an insulator.

In recent years, with the development of electronic industries, demands for high functional, and thin and light components have rapidly increased, and as a result, the printed circuit board with the electronic components also needs to have high-density wirings and a thin thickness.

In particular, in order to cope with the thinning of the printed circuit board, a coreless substrate in which the entire thickness is decreased by removing a core substrate and a signal processing time can be shortened has attracted public attention. Since the coreless substrate does not use the core substrate, the coreless substrate needs a carrier member capable of serving as a support while a manufacturing process. A build-up layer including a circuit layer and an insulating layer is formed on both surfaces of the carrier member according to a general substrate manufacturing method and thereafter, the carrier member is removed to be divided into an upper substrate and a lower substrate, thereby completing the coreless substrate.

The coreless substrate manufacturing method in the prior art uses a laser direct ablation (LDA) method in order to form an opening in solder resist. In the LDA method, due to a limit in a laser spot size, when the size of the opening is large, a processing time is extended. Further, since laser processing should be performed several times, a process is complicated and a cost is increased.

### SUMMARY OF THE INVENTION

The present invention has been made in an effort to provide a method of manufacturing a coreless substrate that forms an opening by patterning a dry film for forming the opening onto one surface of a carrier, separating the carrier from the substrate, and removing only the dry film for forming the opening.

According to a preferred embodiment of the present invention, there is provided a method of manufacturing a coreless substrate, including: (A) patterning a dry film for forming an opening on one surface of a carrier; (B) forming a first protection layer in the carrier patterned with the dry film for forming the opening; (C) forming a circuit layer including a pad on the first protection layer; (D) forming a build-up layer on the first protection layer with the circuit layer; (E) separating the carrier from the first protection layer after forming the build-up layer; and (F) exposing the pad by removing the dry film for forming the opening from the first protection layer.

Herein, in step (F), the dry film for forming the opening may be peeled and removed.

Further, step (A) may include: forming the dry film on one surface of the carrier member; and patterning the dry film through exposure and development.

The method may further include removing the first protection layer remaining in the pad, after step (F).

The method may further include forming a surface treatment layer in the pad, after step (F).

In addition, the surface treatment layer may be an organic solderability preservative (OSP) processing layer or an electroless nickel immersion gold (ENIG) layer.

The method may further include forming a second protection layer on the build-up layer, after step (D).

Moreover, the first protection layer may be solder resist or an ajinomoto build-up film (ABF).

Moreover, the second protection layer may be solder resist or an ajinomoto build-up film (ABF).

Besides, the carrier may include an insulating layer and metal foils formed on both surfaces of the insulating layer.

Further, the metal foils may be copper foils.

### BRIEF DESCRIPTION OF THE DRAWINGS

FIGS. 1 to 10 are cross-sectional views showing a method of manufacturing a coreless substrate in sequence according to a preferred embodiment of the present invention.

### DESCRIPTION OF THE PREFERRED EMBODIMENTS

Prior to this, terms or words used in the specification and the appended claims should not be construed as normal and dictionary meanings and should be construed as meanings and concepts which conform with the spirit of the present invention according to a principle that the inventor can properly define the concepts of the terms in order to describe his/her own invention in the best way.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted.

Hereinafter, a preferred embodiment of the present invention will be described in detail with reference to the accompanying drawings.

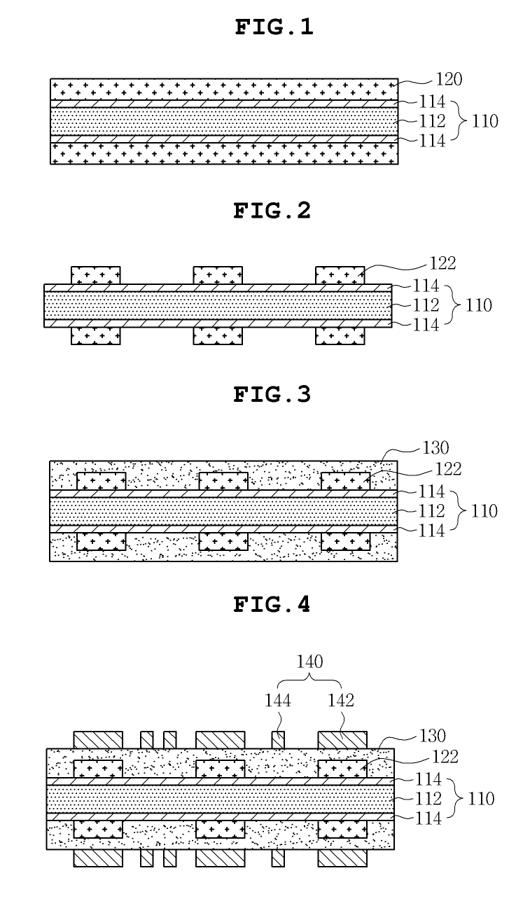

As shown in FIGS. 1 to 9, a method of manufacturing a coreless substrate according to a preferred embodiment of the present invention includes: (A) patterning a dry film 122 for forming an opening on one surface of a carrier 110, (B) forming a first protection layer 130 in the carrier 110 patterned with the dry film 122 for forming the opening, (C) forming a circuit layer 140 including a pad 142 on the first protection layer 130, (D) forming a build-up layer 150 on the first protection layer 130 with the circuit layer 140, (E) separating the carrier 110 from the first protection layer 130 after forming the build-up layer 150, and (F) exposing the pad 142 by removing the dry film 122 for forming the opening from the first protection layer 130. According to the embodiment of the present invention, by substituting an existing LDA method using a laser, the dry film 122 for forming the opening is patterned in the carrier 110 and the dry film 122 is finally removed after separating the carrier 110, and as a result, a process time and a cost required to form an opening 190 in the first protection layer 130 can be reduced. Hereinafter, the manufacturing method will be sequentially described in detail.

First, the dry film 122 for forming the opening is patterned on one surface of the carrier 110.

In this case, the patterning of the dry film 122 for forming the opening includes forming the dry film 120 on one surface of the carrier member 110 and thereafter, exposing and developing the dry film 120. It will be described below in detail.

First, by front-processing one surface of the carrier 110, an adhesion property of the dry film 120 is improved and thereafter, the dry film 120 can be formed in the carrier 110 through a laminator as shown in FIG. 1.

Next, the dry film 120 is selectively hardened through an exposure process of exposing the dry film 120 to light and only an unhardened part is dissolved with a developer to pattern the dry film 122 for forming the opening as shown in FIG. 2.

Meanwhile, in the carrier 110, metal foils 114 are stacked on both surfaces of the insulating layer 112 and the carrier 110 serves to support the coreless substrate while the manufacturing process. Herein, as the insulating layer 112, a resin insulating layer may be used. As the resin insulating layer, a thermosetting resin such as an epoxy resin, a thermoplastic resin such as polyimide, or a prepreg in which a reinforcing material such as a glass fiber or inorganic filler is impregnated thereinto may be used. The metal foils 114 are not particularly limited, but it is preferable to use a copper foil having high thermal conductivity and excellent rigidity.

Next, as shown in FIG. 3, the first protection layer 130 is formed in the carrier 110 patterned with the dry film 122 for forming the opening. The first protection layer 130 serves to prevent a solder from being applied to the circuit layer while final soldering and prevent the circuit layer from being oxidized. The first protection layer 130 may use solder resist or an ajinomoto build-up film (ABF) as a heat-resistant cladding material having an insulating property. The first protection layer 130 may be formed in the carrier 110 by using a method such as screen printing, roller coating, curtain coating, or spray coating.

Next, as shown in FIG. 4, the circuit layer 140 including the pad 142 is formed on the first protection layer 130. The circuit layer 140 may be formed by using a subtractive method of to stacking a copper foil layer and thereafter, selectively removing the copper foil layer by using corrosion resist, an additive method, a semi-additive process (SAP), and a modified semi-additive process (MSAP) using electroless copper plating and electrolysis copper plating. The pad 142 included in the circuit layer 140 is a part exposed through the opening 190 (see FIG. 8) formed on the first protection layer 130 and a solder ball is formed in the circuit layer, such that an external element such as a semiconductor may be mounted on the coreless substrate through soldering.

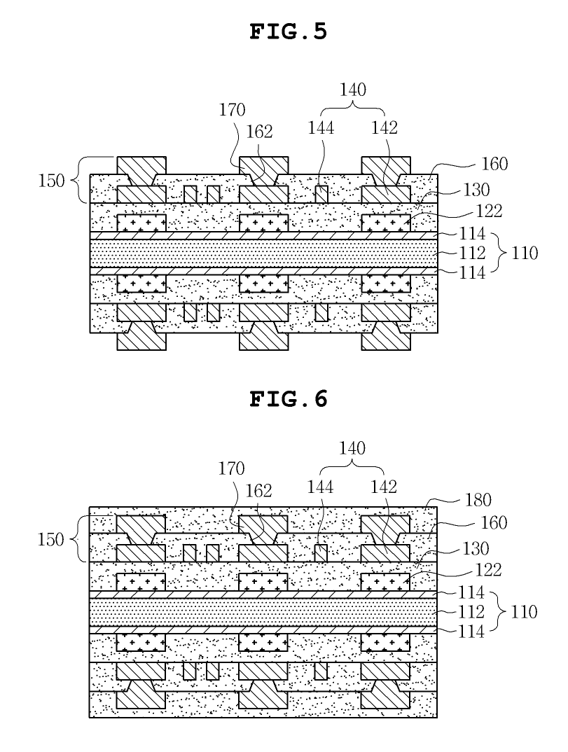

Next, as shown in FIG. 5, the build-up layer 150 is formed on the first protection layer 130 with the circuit layer 140. The build-up layer 150 may be formed by stacking the insulating layer 160 and the circuit layer 170 in sequence according to a generally used method. The method of forming the build-up layer 150 will be described below in detail. The insulating layer 160 is stacked and a via hole 162 is formed by using Yag laser or CO₂ laser. The circuit layer 170 including a via is formed on the insulating layer 160 with the via hole 162 by using the method such as the subtractive method, the additive method, the semi-additive process (SAP), or the modified semi-additive process (MSAP). A single-layer or multi-layer build-up layer 150 may be formed by repeating the process.

In this case, as shown in FIG. 6, the method of manufacturing the coreless substrate may further include forming a second protection layer 180 on the build-up layer 150. The second protection layer 180 serves to prevent an internal circuit layer from being damaged and may use the solder resist or ajinomoto build-up film (ABF). As described above, the second protection layer 180 may be formed by using the method such as the screen printing, roller coating, curtain coating, or spray coating.

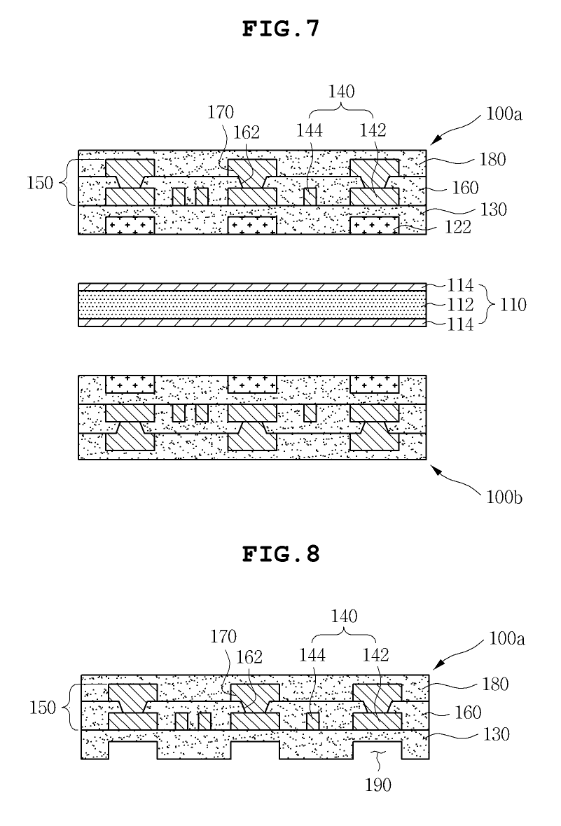

Next, as shown in FIG. 7, the carrier 110 is separated and removed from the first protection layer 130. By removing the carrier 110 through routing, the coreless substrate is separated into an upper substrate 100a and a lower substrate 100b.

Next, as shown in FIG. 8, the pad 142 is exposed by removing the dry film 122 for forming the opening from the first protection layer 130. In the coreless substrate manufacturing method in the prior art, the opening 190 is formed by removing the carrier 110 and thereafter, etching the solder resist by using the laser. However, in the formation of the opening 190 using the laser, the process time is extended as the size of the opening 190 increases due to a limit in the size of a laser spot, and laser processing is required several times and the cost increases. In the embodiment of the present invention, the opening 190 may be formed on the first protection layer 130 by separating and removing the dry film 122 for forming the opening formed on one surface of the carrier 110. Accordingly, the process time required to form the opening 190 can be shortened and since several processing is not required, the cost is saved. Further the process time is constant regardless of the size of the opening 190 to be formed. The pad 142 connected with the external element is exposed by removing the dry film 122 for forming the opening from the first protection layer 130.

Herein, the dry film 122 for forming the opening may be removed by peeling. The dry film 122 for forming the opening is impregnated into or applied with a peeling solution to be peeled off from the coreless substrate. As the peeling solution, alkali metal hydroxides may be used.

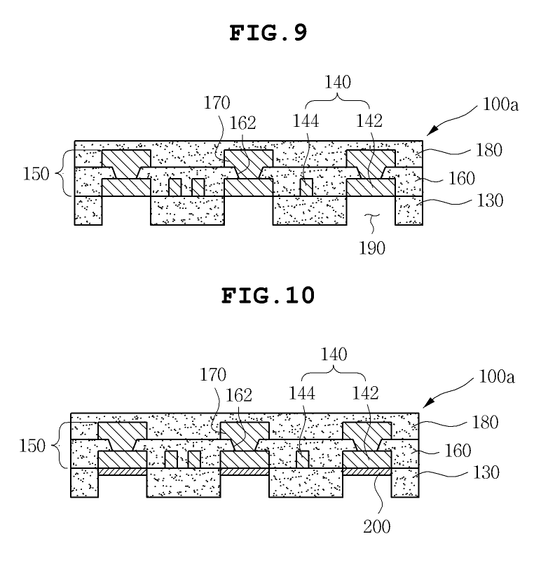

Next, as shown in FIG. 9, the method of manufacturing the coreless substrate may further include removing the first protection layer 130 remaining in the pad 142. When the material of the first protection layer 130 remains in the pad 142 exposed by removing the dry film 122 for forming the opening, electrical connection with the external element is inferior and it is difficult to form a surface treatment layer 200 (see FIG. 10). When the material of the first protection layer 130 remaining in the pad 142 is a little, the material may be removed by using a high-pressure washer. When the material of the first protection layer 130 remaining in the pad 142 is a lot, the material is removed by using a corrosive solution or the laser.

Next, as shown in FIG. 10, the method of manufacturing the coreless substrate may further include forming the surface treatment layer 200 in the pad 142. The surface treatment layer 200 prevents the part of the pad 142 not covered with the first protection layer 130 from being oxidized and improves solderability of components. Further, electrical conductivity is increased by forming the surface treatment layer 200 to improve connection reliability with the external element.

Herein, the surface treatment layer 200 may be an organic solderability preservative (OSP) processing layer or an electroless nickel immersion gold (ENIG) layer.

The organic solderability preservative (OSP) processing layer may be classified into an organic solvent type or a soluble type. The organic solvent type may be applied onto the surface of the pad 142 by using the roll coating and the spray coating. In the case of the soluble type, the surface treatment layer 200 is formed in the pad 142 by using the dipping method.

The electroless nickel immersion gold (ENIG) layer may be formed by plating nickel through the electroless plating process and thereafter, plating immersion gold. The electroless nickel immersion gold (ENIG) layer is excellent in heat resistance and solderability. The surface treatment layer 200 is not limited to the example, but includes hot air solder leveling or all other plated layers.

According to a preferred embodiment of the present invention, a dry film for forming an opening is formed on one surface of a carrier and the carrier is finally separated through a build-up process, and only the dry film for forming the opening is removed to expose a pad, thereby shortening a process time for forming the opening.

According to the preferred embodiment of the present invention, since the dry film for forming the opening can be removed at one time by using peeling, a process is simple and a cost can be reduced.

Although the preferred embodiments of the present invention have been disclosed for illustrative purposes, they are for specifically explaining the present invention and thus a method of manufacturing a coreless substrate according to the present invention is not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A method of manufacturing a coreless substrate, comprising:
(A) patterning a dry film for forming an opening on one surface of a carrier;
(B) forming a first protection layer in the carrier patterned with the dry film for forming the opening;
(C) forming a circuit layer including a pad on the first protection layer;
(D) forming a build-up layer on the first protection layer with the circuit layer;
(E) separating the carrier from the first protection layer after forming the build-up layer; and
(F) exposing the pad by removing the dry film for forming the opening from the first protection layer.

2. The method of manufacturing a coreless substrate as set forth in claim 1, wherein in step (F), the dry film for forming the opening is peeled and removed.

3. The method of manufacturing a coreless substrate as set forth in claim 1, wherein step (A) includes:
forming the dry film on one surface of the carrier member; and
patterning the dry film through exposure and development.

4. The method of manufacturing a coreless substrate as set forth in claim 1, further comprising removing the first protection layer remaining in the pad, after step (F).

5. The method of manufacturing a coreless substrate as set forth in claim 1, further comprising forming a surface treatment layer in the pad, after step (F).

6. The method of manufacturing a coreless substrate as set forth in claim 5, wherein the surface treatment layer is an organic solderability preservative (OSP) processing layer or an electroless nickel immersion gold (ENIG) layer.

7. The method of manufacturing a coreless substrate as set forth in claim 1, further comprising forming a second protection layer on the build-up layer, after step (D).

8. The method of manufacturing a coreless substrate as set forth in claim 1, wherein the first protection layer is solder resist or an ajinomoto build-up film (ABF).

9. The method of manufacturing a coreless substrate as set forth in claim 7, wherein the second protection layer is solder resist or an ajinomoto build-up film (ABF).

10. The method of manufacturing a coreless substrate as set forth in claim 1, wherein the carrier includes an insulating layer and metal foils formed on both surfaces of the insulating layer.

11. The method of manufacturing a coreless substrate as set forth in claim 10, wherein the metal foils are copper foils.
